(19) United States
(12) Patent Application Publication
(10) Pub. No.: US 2024/0168718 A1
(43) Pub. Date: May 23, 2024

(54) CIRCUIT BASED ON DIGITAL DOMAIN IN-MEMORY COMPUTING

(71) Applicant: NANJING HOUMO TECHNOLOGY CO., LTD., Nanjing, Jiangsu (CN)

(72) Inventors: Xin SI, Nanjing, Jiangsu (CN); Liang CHANG, Nanjing, Jiangsu (CN); Liang CHEN, Nanjing, Jiangsu (CN); Zhao Hui SHEN, Nanjing, Jiangsu (CN); Qiang WU, Nanjing, Jiangsu (CN)

(73) Assignee: NANJING HOUMO TECHNOLOGY CO., LTD., Nanjing, Jiangsu (CN)

(21) Appl. No.: 18/283,963

(22) PCT Filed: Mar. 25, 2022
(86) PCT No.: PCT/CN2022/082985

§ 371 Date: Sep. 25, 2023

(30) Foreign Application Priority Data
Mar. 26, 2021 (CN) 202110323034.4

(51) Int. Cl. G06F 7/544; G06F 7/501; G11C 11/408; G11C 11/4096

(52) U.S. Cl. CPC G06F 7/5443; G06F 7/501; G11C 11/4087; G11C 11/4096

(57) ABSTRACT

In an embodiment of the disclosure, disclosed is a circuit based on in-memory computing in a digital domain, including: an array of computational storage cells, the computational storage cells including a preset number of data storage cells and a preset number of single-bit multipliers in one-to-one correspondence; an adder tree configured to accumulate products output by respective computational storage cells to obtain an accumulated result; and a multi-bit input transfer logic configured to convert accumulated results output by the adder tree and corresponding to respective single bits included in the input feature data into a multiply-accumulate result of multi-bit input feature data and multi-bit weight data. An in-memory multiply-accumulation is implemented or multi-bit weight data and input feature data, so that efficiency and energy efficiency density of in-memory computing is improved, “read disturb write” issue caused by a voltage change on bit lines is avoided, and computing stability is improved.

### CROSS-REFERENCE TO RELATED APPLICATIONS

The present application is a U.S. national phase of International Application No. PCT/CN2022/082985, filed on Mar. 25, 2022, which claims priority to Chinese patent application No. CN202110323034.4, filed on Mar. 26, 2021, entitled “Circuit Based on Digital Domain In-Memory Computing”, the disclosures of which are hereby incorporated by reference in their entirety.

### TECHNICAL FIELD

The disclosure relates to a circuit based on in-memory computing in a digital domain.

### BACKGROUND

With a rapid development of applications of artificial intelligence (AI) and Internet of Things (IoT), frequent and massive data transmissions between a central processing unit (CPU) and a memory via a limited bus bandwidth become required.

### SUMMARY

In an embodiment of the disclosure, disclosed is a circuit based on in-memory computing in a digital domain, comprising: an array of computational storage cells, the computational storage cells comprising a preset number of data storage cells and a preset number of single-bit multipliers in one-to-one correspondence, each of the preset number of data storage cells being configured to store a single bit included in weight data and to input the stored single bit into a corresponding single-bit multiplier, and each of the preset number of single-bit multipliers being configured to multiply a single bit included in input weight data and a single bit included in input feature data to obtain a product; an adder tree configured to accumulate products output by respective computational storage cells to obtain an accumulated result; and a multi-bit input transfer logic configured to convert accumulated results output by the adder tree and corresponding to respective single bits included in the input feature data into a multiply-accumulate result of multi-bit input feature data and multi-bit weight data.

In some embodiments, the circuit further comprises: at least one word line driver, each corresponding to a group of computational storage cells; an address decoder configured to select a target computational storage cell from the array of computational storage cells according to an externally input address signal; a data read/write interface configured to write the weight data into the target computational storage cell; and at least one input line driver configured to input respective single bits included in the input feature data respectively into the preset number of single-bit multipliers.

In some embodiments, the circuit further comprises a time controller configured to output a clock signal, the at least one input line driver is further configured to input sequentially respective single bits included in the input feature data respectively into the preset number of single-bit multipliers according to the clock signal, the adder tree is further configured to accumulate sequentially the products output by respective computational storage cells according to the clock signal to obtain the accumulated result, and the multi-bit input transfer logic is further configured to convert sequentially, according to the clock signal, accumulated results output by the adder tree and corresponding to respective single bits included in the input feature data.

In some embodiments, the adder tree comprises at least two adders, and each adder of the at least two adders is configured to accumulate bits corresponding to the adder and included in the products output by respective computational storage cells to obtain a sub-accumulated result corresponding to the adder. The circuit further comprises a multiply-accumulator configured to perform a multiply-accumulate operation on respective sub-accumulated results to obtain the accumulated result.

In some embodiments, the at least two adders comprise a first adder and a second adder, the first adder corresponds to a higher bit of a corresponding number of bits in the product, and the second adder corresponds to a lower bit of the corresponding number of bits in the product. The multiply-accumulator comprises a multiplication sub-circuit and a first addition sub-circuit, the multiplication sub-circuit is configured to multiply the sub-accumulated result corresponding to the first adder with a preset numerical value, and the first addition sub-circuit is configured to add a result output by the multiplication sub-circuit with the sub-accumulated result corresponding to the second adder to obtain the accumulated result.

In some embodiments, the higher bit of the corresponding number of bits is the highest bit of the product, and the lower bit of the corresponding number of bits is another bit in the product different from the highest bit.

In some embodiments, the multi-bit input transfer logic comprises a shifter and a second addition sub-circuit, and the shifter and the second addition sub-circuit are configured to perform cyclically: inputting an accumulated result corresponding to a highest bit of the input feature data into the shifter, inputting a shifted accumulated result and an accumulated result corresponding to an adjacent lower bit into the second addition sub-circuit, inputting an added accumulated result into the shifter, and inputting another shifted accumulated result and another accumulated result corresponding to another adjacent lower bit into the second addition sub-circuit again, the multiply-accumulate result being obtained until an accumulated result corresponding to a lowest bit of the input feature data and yet another shifted accumulated result are input into the second addition sub-circuit.

In some embodiments, the multi-bit input transfer logic comprises a target number of shifters and a third addition sub-circuit, and the target number is a number of bits included in the input feature data minus one. Each of the target number of shifters is configured to shift an input accumulated result by a corresponding number of bits. The third addition sub-circuit is configured to add shifted accumulated results respectively output by the target number of shifters to obtain the multiply-accumulate result.

In some embodiments, the circuit further comprises a mode selection sub-circuit configured to select a current operation mode of the circuit according to an input mode selection signal, and the operation mode comprises a normal read/write mode and a multi-bit multiply-accumulate mode. In the normal read/write mode, the address decoder is further configured to select a target word line driver from the at least one word line driver according to an externally input write address signal or read address signal, and the data read/write interface is further configured to write data to data storage cells included in respective computational storage cells corresponding to the selected target word line driver based on the write address signal, or read out data from the data storage cells included in respective computational storage cells corresponding to the selected target word line driver based on the read address signal.

In some embodiments, the single-bit multiplier comprises a NOR gate configured to perform a NOR operation on a single bit included in inverted weight data and a single bit included in inverted input feature data to obtain single-bit product.

In the circuit based on in-memory computing in the digital domain disclosed in the above embodiments of the disclosure, a principle of multi-bit data multiplication is utilized, single-bit multipliers are arranged in the array of computational storage cells for multiplying each single bit included in the weight stored in each data storage cell respectively with each single bit included in the input feature data to obtain a plurality of products, respective products corresponding to respective bits are accumulated by the adder tree to obtain a plurality of accumulated results, and subsequently, the multi-bit input transfer logic is utilized to shift and accumulate respective accumulated results to obtain a multiply-accumulate result of the weight data and the input feature data. In the embodiment of the disclosure, an in-memory multiply-accumulation is implemented for multi-bit weight data and multi-bit input feature data, and the efficiency and energy efficiency density of the in-memory computing are improved. Compared with the manner of implementing the multiply-accumulation by a voltage difference between two-bit lines, the “read disturb write” issue caused by the voltage change on the bit lines may be avoided in the embodiment of the disclosure, thus improving computing stability. The recognition speed of the neural network may be improved greatly by applying this circuit to the computations of a deep neural network.

The solution of the disclosure will be described in further detail with reference to the drawings and embodiments.

### BRIEF DESCRIPTION OF THE DRAWINGS

The above and other targets, features and advantages of the disclosure will become more apparent by describing the embodiments of the disclosure in more detail with reference to the accompanying drawings. The accompanying drawings are provided to enhance comprehension of the embodiments of the disclosure and constitute a part of the specification, and together with the embodiments of the disclosure, serve to explain the disclosure, but do not constitute a limitation of the disclosure. In the drawings, the like reference numerals may generally represent the like parts or steps.

FIG. 1 is a structural diagram of a circuit based on in-memory computing in a digital domain disclosed in an exemplary embodiment of the disclosure.

FIG. 2 is another structural diagram of a circuit based on in-memory computing in a digital domain disclosed in an exemplary embodiment of the disclosure.

FIG. 3 is a timing diagram of a circuit based on in-memory computing in a digital domain disclosed in an exemplary embodiment of the disclosure.

FIG. 4 is an exemplary structural diagram of an adder tree in a circuit based on in-memory computing in a digital domain disclosed in an exemplary embodiment of the disclosure.

FIG. 5 is an exemplary structural diagram of a multiply-accumulator in a circuit based on in-memory computing in a digital domain disclosed in an exemplary embodiment of the disclosure.

FIG. 6 is an exemplary structural diagram of a multi-bit input transfer logic in a circuit based on in-memory computing in a digital domain disclosed in an exemplary embodiment of the disclosure.

FIG. 7 is an exemplary structural diagram of another multi-bit input transfer logic in a circuit based on in-memory computing in a digital domain disclosed in an exemplary embodiment of the disclosure.

### DETAILED DESCRIPTION

With a rapid development of applications of artificial intelligence (AI) and Internet of Things (IoT), frequent and massive data transmissions between a central processing unit (CPU) and a memory via a limited bus bandwidth become required, which is also recognized as a bottleneck in the current Von Neumann architecture. A deep neural network, as one of successful algorithms currently available to image recognition in a field of AI, requires a large number of operations, including reading and writing, multiplication, and addition, on input feature data (e.g., an input activation) and weight data, which also means a requirement for a larger number of data transmissions and more energy consumption. In various AI tasks, the energy consumed by reading and writing data may be much larger than that consumed by data computations. For example, a deep neural network processor based on the traditional Von Neumann architecture may be usually configured to store both input feature data and weight data in corresponding memories, to send them via a bus to corresponding digital operation circuits for multiply-accumulate (MAC, also denoted as “multiplication and computation” herein) operations, and then to read out operation results. Due to a limited number of memory interfaces for reading data, the reading bandwidth for the weight data (i.e., the number of weights readable per unit cycle) may not be large enough, so that the number of multiply-accumulate operations per unit cycle is limited, and further, an overall throughput of a system may also be affected.

In order to break the bottleneck in the Von Neumann architecture, an in-memory computing architecture has been proposed, which may support different logic or multiply-accumulate operations while retaining the storage and read/write functions inherent in the memory, so that, in addition to reducing greatly the frequent bus interactions between the CPU and the memory, the amount of data migration may be further reduced and the energy efficiency of the system may be improved. With such deep neural network processor based on the in-memory computing architecture, the weight data may be directly subjected to multiply-accumulate operations without being read, and the multiply-accumulate results may be obtained directly. Therefore, the throughput of the system may no longer be limited by the limited number of memory interfaces for reading data.

Hereinafter, exemplary embodiments of the disclosure will be described in detail with reference to the accompanying drawings. Obviously, the described embodiments are only part of the embodiments of this disclosure, not all the embodiments of this disclosure, and it is understood that this disclosure is not limited by the exemplary embodiments described herein.

It is noted that the relative arrangement, numerical expressions and numerical values of components and steps set forth in these embodiments do not limit the scope of the disclosure unless otherwise specified.

It is understood by those skilled in the art that terms such as “first” and “second” in the embodiments of this disclosure are only used to distinguish different steps, devices or modules, and do not represent any specific technical meaning or their inevitable logical order.

It is also understood that in the embodiments of the disclosure, “a plurality of” may refer to two or more, and “at least one” may refer to one, two or more.

It is also understood that any component, data or structure mentioned in the embodiments of the disclosure may generally be understood as one or more components, data or structures unless explicitly defined or given contrary enlightenment in the context.

In addition, the term “and/or” herein signifies an association relationship between associated objects, denoting the possibility of three different relationship types. For example, A and/or B may mean A alone, A and B, and B alone. In addition, the character “/” in this disclosure generally indicates that the associated objects have an “or” relationship.

It is also understood that the description of various embodiments in this disclosure focuses on the differences between various embodiments, and the same or similar parts may serve as references for each other, and will not be repeated for the sake of brevity.

Meanwhile, it is understood that for convenience of description, the dimensions of various parts shown in the drawings are not drawn according to the actual proportional relationship.

The description of at least one exemplary embodiment below is only illustrative, and in no way should it be taken as any limitation on the disclosure, its application or uses.

Techniques, methods and devices known to those skilled in the relevant fields may not be discussed in detail, but they are regarded as part of the specification under appropriate circumstances.

It is noted that similar reference numerals and letters indicate similar items in the following figures, so once an item is defined in one figure, it will not be further discussed in the following figures.

### Overview

A traditional in-memory computing design based on a 6T static random-access memory (SRAM) is suitable for a classifier based on single-bit weights, and may support the following function:

$$\begin{matrix}D out = sgn ( {\sum }_{i = 1}^{N} {W}_{i} \times {IN}_{i} ) \\ sgn ( x ) = \{ \begin{matrix}1 , x \geq 0 \\ 0 , x < 0\end{matrix}\end{matrix}$$

where Dout is an output of the classifier, N is the number of simultaneous multiply-accumulate operations, sgn is an activation function, Wᵢ is single-bit weight data, and INᵢ is 5-bit input feature data.

The classifier may include a 128×128-bit 6T SRAM array, 128 parallel 5-bit word line (WL) digital-to-analog converters (WLDACs), 128 rail-to-rail comparators for computing Dout, and a WL driver and an IO for reading/writing in a general memory.

Like a general in-memory design circuit, this design may work in two modes, i.e., a SRAM mode and a classification mode. In the SRAM mode, the circuit may perform normal read/write operations on SRAM cells, which is the same as a traditional SRAM circuit. In the classification mode, the 128 5-bit input feature data may be converted into 128 WLs (WL₀ to WL₁₂₇) via the WLDAC, voltage differences between BL and BLB in each column may then correspond to a multiply-accumulate result of the 128 5-bit inputs IN and a 1-bit weight W, and a classification result may be obtained through a comparator by determining whether the multiply-accumulate result is positive or negative.

Due to an influence of Process, Voltage and Temperature (PVT), there may be an error for the voltage difference between BL and BLB compared to a theoretical multiply-accumulate result of the 5-bit input IN and 1-bit weight W, and an offset of the comparator may also affect the determination. Thus, the classifier formed by each column is a weak classifier. In order to improve the performance of the classifier, in this design, multiple weaker classifiers are utilized to form a boosted strong classifier with a better performance.

Defects of this Circuit May Include:
1. the voltage value on BL may vary with the computation result in a case where multiple WLs are enabled in parallel, and thus, in a case where this voltage value is lower than a write margin for a single SRAM cell, this design may still suffer a “read disturb write” issue because a cell which should have originally stored 1 may be written erroneously with 0;
2. each strong classifier is formed by M weak classifiers and may only make a determination for two kinds of classification results, and thus for a data set including n classification results, [n×(n−1)]/2 strong classifiers are required to make a single determination for the classification results, and for an MNIST data set where n=10, 45 strong classifiers are required to form a complete classifier, leading to an excessive area overhead for example with an increase of the number of classification results in a recognition data set; and
3. due to the impact of computational accuracy, this design cannot support efficiently a neural network model requiring higher accurate computation results, such as a convolutional neural network.

### Exemplary Structure

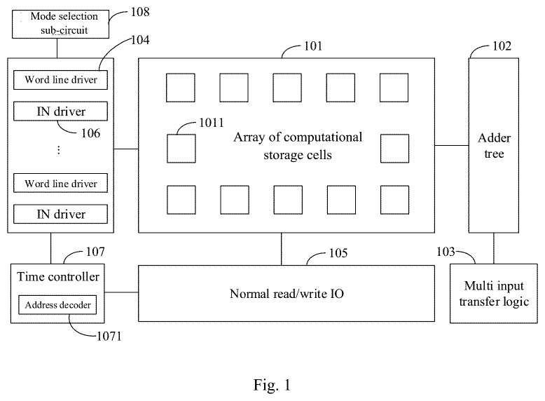

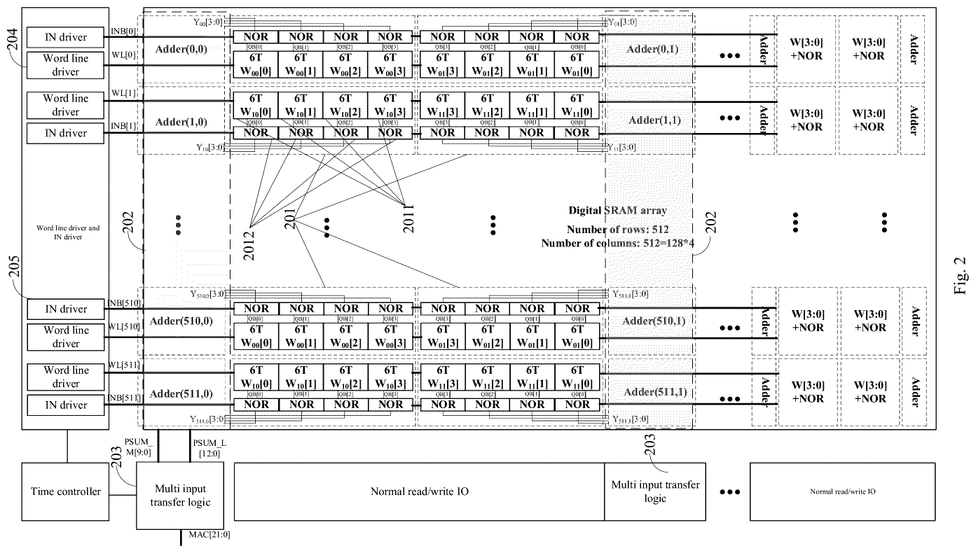

FIG. 1 is a structural diagram of a circuit based on in-memory computing in a digital domain disclosed in an exemplary embodiment of the disclosure. Respective components in the circuit may be integrated onto one chip, or be arranged on different chips or circuit boards among which links for data communication are established. As shown in FIG. 1, the circuit comprises an array of computational storage cells 101, an adder tree 102, and a multi-bit input transfer logic (also denoted as “multi input transfer logic” herein) 103. The array of computational storage cells 101 includes a plurality of computational storage cells 1011. For example, as shown in FIG. 2, the array of computational storage cells 201 includes computational storage cells arranged in 512 rows and 128 columns, wherein the computational storage cells in the array of computational storage cells 201 comprise a preset number of data storage cells (as shown by 2011 in FIG. 2) and a preset number of single-bit multipliers (as shown by 2012 in FIG. 2) in one-to-one correspondence. As shown in FIG. 2, in a case where the preset number is four, each of the 128 columns of computational storage cells comprises 4 columns of data storage cells. The computational storage cell 2011 comprises four 6T SRAM data storage cells and four single-bit multipliers (each single-bit multiplier comprising a 4T NOR gate and thus being denoted by NOR). For each data storage cell, its data output end is connected with a data input end of a single-bit multiplier.

In this embodiment, each of the preset number of data storage cells is configured to store a single bit included in the weight data and to input the stored single bit into a corresponding single-bit multiplier. The weight data is usually weight data in a neural network. As an example, four single bits Woo[0], Woo[1], Woo[2] and Woo[3] included in 4-bit weight data are stored respectively in the four data storage cells shown by 2011 in FIG. 2. Respective single bits are input to corresponding single-bit multipliers, respectively.

In this embodiment, each of the preset number of single-bit multipliers is configured to multiply a single bit included in input weight data and a single bit included in input feature data to obtain a product.

The number of bits of the input feature data and the number of bits of the weight are usually the same, for example, both being 4. As an example, assuming weight data W₀₀=1010, that is, W₀₀[0]=0, W₀₀[1]=1, W₀₀[2]=0 and W₀₀[3]=1 in FIG. 2, and input feature data IN₀=0101, then IN₀₀[0]=1 is input into the single-bit multipliers respectively corresponding to W₀₀[0], W₀₀[1], W₀₀[2] and W₀₀[3] in the figure, and the four single-bit multipliers operate so that W₀₀[0]×IN₀₀[0], W₀₀ [1]×IN₀₀ [0], W₀₀ [2]×IN₀₀ [0] and W₀₀ [4]×IN₀₀ [0] are computed and thus a product S0[0]=1010 is obtained. Then, in the same way, IN₀₀[1]=0, IN₀₀[2]=1 and IN₀₀[3]=0 are sequentially input to the four single-bit multipliers for single-bit multiplications with W₀₀[0], W₀₀[1], W₀₀[2] and W₀₀[3], respectively, and products S1[0]=0000, S2[0]=1010 and S3[0]=0000 are obtained.

In this embodiment, the adder tree 102 is configured to accumulate the products output by respective computational storage cells to obtain an accumulated result. As shown in FIG. 2, each column of computational storage cells corresponds to an adder tree 202, and INB[0] to INB[511] are 512 4-bit input feature data. The adder tree 202 in FIG. 2 comprises 512 adders, each adder corresponding to a computational storage cell for storing a corresponding product, and the adder tree 202 outputs an accumulated result. It is noted that one single bit of 512 4-bit input feature data is taken for multiplication in each computing cycle, that is, all of the 512 4-bit input feature data may be computed in four computing cycles, and the accumulated results corresponding respectively to the four computing cycles are as follows:

S0=Σₖ₌₀⁵¹¹(W_{0,k}[3:0]×INB[k][0]),

S1=Σₖ₌₀⁵¹¹(W_{0,k}[3:0]×INB[k][1]),

S2=Σₖ₌₀⁵¹¹(W_{0,k}[3:0]×INB[k][2]),

S3=Σₖ₌₀⁵¹¹(W_{0,k}[3:0]×INB[k][3]),

where INB[k][0] to INB[k][3] are four single bits of the input feature data INB[k], respectively.

In this embodiment, the multi-bit input transfer logic 103 is configured to convert accumulated results output by the adder tree 102 and corresponding to respective single bits included in the input feature data into a multiply-accumulate result of multi-bit input feature data and multi-bit weight data. As shown in FIG. 2, the multi-bit input transfer logic 203 receives the accumulated results PSUM_M and PSUM_L, and outputs the multiply-accumulate result MAC, wherein the PSUM_M and PSUM_L will be described in the following optional implementations.

Generally, respective accumulated results may be shifted and accumulated to obtain the multiply-accumulate result of the weight data and the input feature data. As an example, according to the principle of multi-bit data multiplication, the above S0-S3 need to be shifted left by 0, 1, 2 and 3 bits, respectively, and then the shifted data are added, so that the multiply-accumulate result of multi-bit data is obtained. The above shift accumulation may be implemented by arranging a shifter and an adder in the circuit.

In the method disclosed in the above embodiment of the disclosure, the principle of multi-bit data multiplication is utilized, single-bit multipliers are arranged in the array of computational storage cells for multiplying each single bit included in the weight stored in each data storage cell respectively with each single bit included in the input feature data to obtain a plurality of products, respective products corresponding to respective bits are accumulated by the adder tree to obtain a plurality of accumulated results, and subsequently, the multi-bit input transfer logic is utilized to shift and accumulate respective accumulated results to obtain a multiply-accumulate result of the weight data and the input feature data. In the embodiment of the disclosure, an in-memory multiply-accumulation is implemented for multi-bit weight data and multi-bit input feature data, and the efficiency and energy efficiency density of the in-memory computing are improved. Compared with the manner of implementing the multiply-accumulation by a voltage difference between two-bit lines, the “read disturb write” issue caused by the voltage change on the bit lines may be avoided in the embodiment of the disclosure, thus improving computing stability. The recognition speed of the neural network may be improved greatly by applying this circuit to the computations of a deep neural network.

In some optional implementations, as shown in FIG. 1, the circuit may further comprise:
at least one word line (WL) driver 104, each corresponding to a group of computational storage cells, wherein the number of computational storage cells included in the group of computational storage cells may be at least one, and for example, as shown in FIG. 2, each word line driver 204 corresponds to a row of 128 computational storage cells;
an address decoder 1071 (usually included in a time controller 107) configured to select a target computational storage cell from the array of computational storage cells according to an externally input address signal;
a data read/write interface (also denoted as “normal read/write TO” herein) 105 configured to write the weight into the target computational storage cell, wherein for example, the externally input address signal is converted into the corresponding word line driver by the address decoder in the time controller to enable a word line selected by a row address, and the written weight data is transmitted to a bit line (BL/BLB) on a corresponding row via a write interface in the data read/write interface, and then is written into the data storage cell by an input voltage on the bit line; and
at least one input line driver (also denoted as “IN driver” herein) 106 configured to input respective single bits included in the input feature data respectively into the preset number of single-bit multipliers, and as shown in FIG. 2, the single bits included in the input feature data INB are input to the corresponding single-bit multipliers by the plurality of input line drivers 205.

By arranging the word line driver, the input line driver, the address decoder and the data read/write interface in the circuit, the weight data may be written into the data storage cells in a normal data read/write mode while controlling input of each single bit included in the input feature data, so that a flow of data multiply-accumulation is controlled accurately and efficiently, and the accuracy and efficiency of computations are improved.

In some optional implementations, the circuit further comprises a time controller 107 configured to output a clock signal.

The at least one input line driver 106 is further configured to input sequentially respective single bits included in the input feature data respectively into the preset number of single-bit multipliers according to the clock signal.

The adder tree 102 is further configured to accumulate sequentially the products output by respective computational storage cells according to the clock signal to obtain the accumulated result.

The multi-bit input transfer logic 103 is further configured to convert sequentially accumulated results output by the adder tree and corresponding to respective single bits included in the input feature data according to the clock signal.

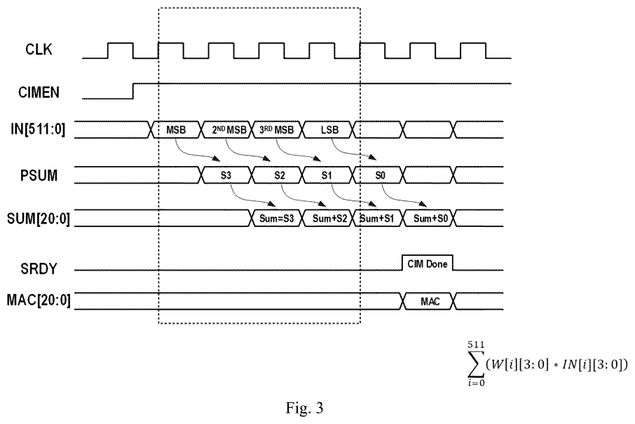

FIG. 3 shows a timing diagram of an embodiment of the disclosure, wherein CLK represents a clock signal, MIEN represents an in-memory computing enable signal which is active at a high level, IN represents input feature data, PSUM represents an accumulated result, SUM represents data obtained after a multi-bit input conversion for the accumulated result, SRDY represents a multiply-accumulation completed indication signal (CIM Done), and MAC represents a multiply-accumulate result. FIG. 3 shows a process of a multiply-accumulation for 4-bit data, and one 4-bit data is processed in four clock cycles. As shown in FIG. 3, for each of the input feature data IN[0]-IN[511], one single bit included in the input feature data is received in each clock cycle, and corresponding bits included in respective input feature data are accumulated in each cycle to obtain accumulated results S3, S2, S1 and S0. Then, the accumulated results are shifted and accumulated, and the multiply-accumulate result
(i.e Σₖ₌₀⁵¹¹(W_{0,k}[3:0]×IN[k][3])) is output via an MAC signal line.

By arranging the time controller 107 in the circuit, in the in-memory computing process, the multiply-accumulation may be performed in the order of single bits under the control of the clock signal, thus saving the single-bit multipliers for receiving the input feature data, saving on-chip resources and improving the operation efficiency.

In some optional implementations, the circuit may further comprise a mode selection sub-circuit 108 configured to select a current operation mode of the circuit according to an input mode selection signal, and an operation mode comprises a normal read/write mode and a multi-bit multiply-accumulate mode. For example, in a case where the current mode is selected as the multi-bit multiply-accumulate mode according to the mode selection signal, a multi-bit multiply-accumulation is performed using the input line driver, the single-bit multiplier, the adder tree, the multi-bit input transfer logic, and the like.

In the normal read/write mode, the address decoder 1071 is further configured to select a target word line driver from the at least one word line driver according to an externally input write address signal or read address signal. The data read/write interface 105 is further configured to write data to data storage cells included in respective computational storage cells corresponding to the selected target word line driver based on the write address signal, or read out data from the data storage cells included in respective computational storage cells corresponding to the selected target word line driver based on the read address signal.

For example, during a write operation in the normal read/write mode, the externally input address signal is converted into the corresponding word line driver through the address decoder 1071 in the time controller 107, so that a word line selected by a row address is enabled, and the written data are transmitted to a bit line (BL/BLB) on a corresponding data storage cell through a write interface in the data read/write interface, and then is written into the data storage cell through an input voltage on the bit line.

During a read operation in the normal read/write mode, the externally input address signal is converted into the corresponding word line driver through the address decoder in the time controller, so that a word line selected by a row address is enabled, and storage data in the corresponding data storage cell are manifested on a corresponding bit line (BL/BLB), and then is read out through a read interface in the data read/write interface.

By arranging the mode selection sub-circuit 108, the array of computational storage cells may be flexibly used to perform normal read/write of data or in-memory multi-bit multiply-accumulation, thus improving the use flexibility of the array of computational storage cells and enriching the application scenarios of the array of computational storage cells.

In some optional implementations, the adder tree 102 comprises at least two adders (also denoted as “subtrees” herein), and each adder of the at least two adders is configured to accumulate bits corresponding to the adder and included in the products output by respective computational storage cells to obtain a sub-accumulated result corresponding to the adder.

The circuit further comprises:
a multiply-accumulator configured to perform a multiply-accumulate operation on respective sub-accumulated results to obtain the accumulated result.

As an example, the number of the adder trees may be the same as the number of bits of a product. For example, four adder trees are provided, and each adder tree is configured to add collocated single bits in multiple products to obtain four accumulated results s0, s1, s2 and s3. The multiply-accumulator is used for the following computation to obtain the accumulated result:

PSUM=s3*8+s2*4+s1*2+s0.

By providing at least two adders for the adder tree, the accumulation process may be performed in a distributed computing manner, and the complexity of arranging the adder tree is reduced.

In some optional implementations, the at least two adders comprise a first adder and a second adder, the first adder corresponds to a higher bit of a corresponding number of bits in the product, and the second adder corresponds to a lower bit of the corresponding number of bits in the product. As an example, the first adder corresponds to the higher two bits of the product and the second adder corresponds to the lower two bits of the product, that is, the first adder adds data corresponding to the higher two bits of respective products and the second adder adds data corresponding to the lower two bits of respective products.

The multiply-accumulator comprises a multiplication sub-circuit and a first addition sub-circuit, the multiplication sub-circuit is configured to multiply the sub-accumulated result corresponding to the first adder with a preset numerical value, and the first addition sub-circuit is configured to add a result output by the multiplication sub-circuit with the sub-accumulated result corresponding to the second adder to obtain the accumulated result.

As an example, assuming that the product is 4-bit data, the sub-accumulated result output by the first adder is “a” and that the sub-accumulated result output by the second adder is “b”, the accumulated result is PSUM=a*4+b.

By providing two adders for the adder tree, the number of multiplication operations is reduced on the basis of reducing the complexity of arranging the adder tree, thus improving the computing efficiency.

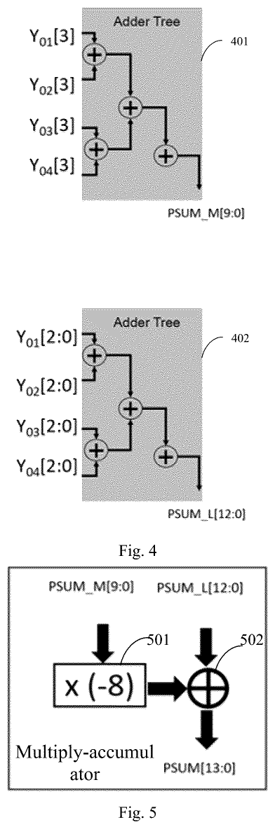

In some optional implementations, the higher bit of the corresponding number of bits is the highest bit (for example, the most significant bit or MSB) of the product, and the lower bit of the corresponding number of bits is another bit in the product different from the highest bit (for example, the second MSB, the third MSB, the least significant bit or LSB, or the like). As shown in FIG. 4, an adder corresponding to the highest bit is represented by 401, the input feature data comprise Y₀₁[3], Y₀₁[3], Y₀₂[3], Y₀₃[3] . . . , an adder corresponding to the lower three bits is represented by 402, the input feature data comprise Y₀₁[2:0], Y₀₁[2:0], Y₀₂[2:0], Y₀₃[2:0] . . . , a sub-accumulated result PSUM_M[9:0] obtained by accumulating the highest bits of 512 products is output by 401, and a sub-accumulated result PSUM_L[12:0] obtained by accumulating the lower three bits of 512 products is output by 402. Accordingly, as shown in FIG. 5, the multiply-accumulator comprises a multiplication sub-circuit 501 and a first addition sub-circuit 502, and the multiplication sub-circuit 501 multiplies PSUM_M[9:0] by a preset value. In a case where the 4-bit product data is a signed number, the weight for the highest bit is −8, and the weights for the other bits are 4, 2 and 1 sequentially. Thus, the preset value is −8 as shown in the figure.

In this implementation, by accumulating the highest bit separately, it is possible to process the signed highest bit separately in a case where the product data is a signed number, thus improving the flexibility of data accumulation.

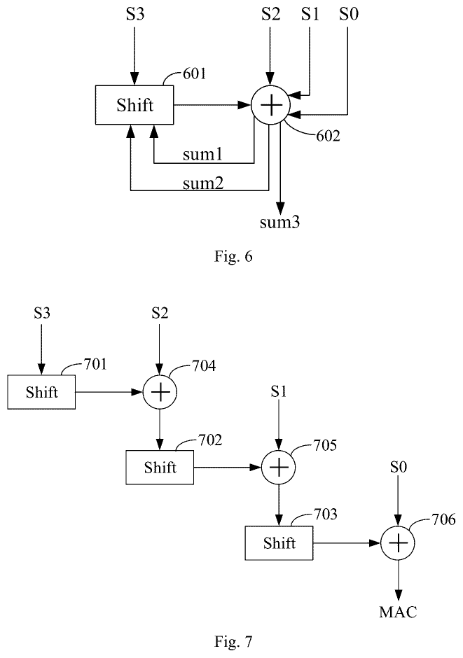

In some optional implementations, as shown in FIG. 6, the multi-bit input transfer logic comprises a shifter 601 and a second addition sub-circuit 602, and the shifter and the second addition sub-circuit are configured to perform cyclically:

inputting an accumulated result corresponding to a highest bit of the input feature data into the shifter, inputting a shifted accumulated result and an accumulated result corresponding to an adjacent lower bit into the second addition sub-circuit, inputting an added accumulated result into the shifter, and inputting another shifted accumulated result and another accumulated result corresponding to another adjacent lower bit into the second addition sub-circuit again, the multiply-accumulate result being obtained until an accumulated result corresponding to a lowest bit of the input feature data and yet another shifted accumulated result are input into the second addition sub-circuit.

As an example, assuming that the input feature data is 4-bit data, the accumulated result S3 corresponding to the highest bit is first input to the shifter 601, and an accumulated result obtained by shifting S3 and the accumulated result S2 corresponding to the second highest bit are input to the second addition sub-circuit 602, to obtain data sum1 after the first shift accumulation. Then, sum1 is input to the shifter 601 again, and sum1 is shifted and input to second addition sub-circuit 602 together with the accumulated result S1, to obtain data sum2 after the second shift accumulation. Then, sum2 is input to the shifter 601 again, and sum2 is shifted and input to the second addition sub-circuit 602 together with the accumulated result S0, to obtain data sum3 after the third shift accumulation, which is the final multiply-accumulate result MAC.

In this implementation, by configuring the multi-bit input transfer logic as a combination of a shifter and an addition sub-circuit, respective accumulated results may be shifted and accumulated cyclically, thus realizing a multi-bit input conversion with a small amount of hardware, saving the space occupied by the circuit and reducing the hardware cost.

In some optional implementations, the multi-bit input transfer logic comprises a target number of shifters and a target number of third addition sub-circuits, and the target number is the number of bits included in the input feature data minus one. For example, the target number is 3.

Each of the target number of shifters is configured to shift the input accumulated result by corresponding number of bits.

The third addition sub-circuits are configured to add the shifted accumulated results respectively output by the target number of shifters to obtain a multiply-accumulate result.

As shown in FIG. 7, both the number of the shifters and the number of the third addition sub-circuits are 3, the accumulated result S3 is input to the first shifter 701, and then the shifted data and the accumulated result S2 are input to the first third addition sub-circuit 704. Then, an addition result is input to the second shifter 702, and the shifted data and the accumulated result S1 are input to the second third addition sub-circuit 705. Subsequently, an addition result is input to the third shifter 703, then the shifted data and the accumulated result S0 are input to the third third addition sub-circuit 706, and the final data is obtained, which is the multiply-accumulate result MAC.

In some optional implementations, the single-bit multiplier comprises a NOR gate configured to perform a NOR operation on a single bit included in inverted weight data and a single bit included in inverted input feature data to obtain single-bit product.

Generally, inverted data W_B may be extracted from the 6T SRAM storing the single bit W included in the weight data, the single bit IN included in the input feature data is then inverted to obtain IN_B, and then W_B and W_B are input into the NOR gate to output the single-bit product. An example truth table is as follows:

| IN | W | IN_B | WB | OUT = IN × W |
|---|---|---|---|---|
| 1 | 1 | 0 | 0 | 1 |
| 1 | 0 | 0 | 1 | 0 |
| 0 | 1 | 1 | 0 | 0 |
| 0 | 0 | 1 | 1 | 0 |

In this implementation, it is simple to adopt the NOR gate to realize the single-bit multiplication, and the complexity of the circuit and the cost of circuit implementation are reduced.

The basic principles of this disclosure have been described above in combination with example embodiments. However, it is noted that the merits, advantages, effects, etc. mentioned in this disclosure are only examples rather than limitations, and cannot be considered as necessary for each embodiment of this disclosure. In addition, the example details disclosed above are only for the purpose of illustration and easy understanding, but not for limitation, and it does not mean that the disclosure must be realized with the above specific details.

All the embodiments in this specification are described in a progressive way, and each embodiment focuses on the differences from other embodiments. The same and similar parts among the embodiments may be referred to one another. As the above system embodiments are basically similar to the method embodiments, the description is relatively simple, and please refer to the description of the method embodiments for relevant information.

The block diagrams of devices, apparatuses, equipment and systems involved in this disclosure are only illustrative examples and are not intended to require or imply that they must be connected, arranged and configured in the manner shown in the block diagrams. As those skilled in the art may recognize, these devices, apparatuses, equipment and systems may be connected, arranged and configured in any way. Words such as “comprise”, “include” and “have” are open words, which mean “including but not limited to” and may be used interchangeably therewith. The terms “or” and “and” as used herein refer to “and/or” and may be used interchangeably therewith unless otherwise indicated in the context. The expression “such as” used here refers to “such as but not limited to” and may be used interchangeably therewith.

The method and apparatus of the disclosure may be implemented in many ways. For example, the method and apparatus of the disclosure may be implemented by software, hardware, firmware or any combination thereof. The above order of steps in the method is only for illustration, and the steps of the method of the disclosure are not limited to the order described above, unless otherwise specified. Further, in some embodiments, the disclosure may also be implemented as programs recorded in a recording medium, which include machine-readable instructions for implementing the method according to the disclosure. Thus, the disclosure also covers a recording medium storing programs for executing the method according to the disclosure.

It is also noted that in the apparatus, equipment and method of the disclosure, each component or step may be decomposed and/or recombined. Such decomposition and/or recombination are regarded as equivalent schemes of the disclosure.

The above description of the disclosed aspects is provided to enable any person skilled in the art to make or use the disclosure. Various modifications to these aspects will be obvious to those skilled in the art, and the general principles defined herein may be applied to other aspects without departing from the scope of this disclosure. Therefore, the disclosure is not intended to be limited to the aspects shown herein, but is to be accorded the widest scope consistent with the principles and novel features disclosed herein.

The foregoing description has been presented for purposes of illustration and description. Furthermore, this description is not intended to limit the embodiments of the disclosure to the forms disclosed herein. Although several exemplary aspects and embodiments have been discussed above, those skilled in the art will recognize certain variations, modifications, changes, additions and sub combinations thereof.

1. A circuit based on in-memory computing in a digital domain, comprising:
an array of computational storage cells, the computational storage cells comprising a preset number of data storage cells and a preset number of single-bit multipliers in one-to-one correspondence, each of the preset number of data storage cells being configured to store a single bit included in weight data and to input the stored single bit into a corresponding single-bit multiplier, and each of the preset number of single-bit multipliers being configured to multiply a single bit included in input weight data and a single bit included in input feature data to obtain a product;
an adder tree configured to accumulate products output by respective computational storage cells to obtain an accumulated result; and
a multi-bit input transfer logic configured to convert accumulated results output by the adder tree and corresponding to respective single bits included in the input feature data into a multiply-accumulate result of multi-bit input feature data and multi-bit weight data.

2. The circuit according to claim 1, further comprising:
at least one word line driver, each corresponding to a group of computational storage cells;
an address decoder configured to select a target computational storage cell from the array of computational storage cells according to an externally input address signal;
a data read/write interface configured to write the weight data into the target computational storage cell; and
at least one input line driver configured to input respective single bits included in the input feature data respectively into the preset number of single-bit multipliers.

3. The circuit according to claim 2, further comprising:
a time controller configured to output a clock signal,
the at least one input line driver being further configured to input sequentially respective single bits included in the input feature data respectively into the preset number of single-bit multipliers according to the clock signal,
the adder tree being further configured to accumulate sequentially the products output by respective computational storage cells according to the clock signal to obtain the accumulated result, and
the multi-bit input transfer logic being further configured to convert sequentially, according to the clock signal, accumulated results output by the adder tree and corresponding to respective single bits included in the input feature data.

4. The circuit according to claim 1, wherein the adder tree comprises at least two adders, and each adder of the at least two adders is configured to accumulate bits corresponding to the adder and included in the products output by respective computational storage cells to obtain a sub-accumulated result corresponding to the adder; and
the circuit further comprises:
a multiply-accumulator configured to perform a multiply-accumulate operation on respective sub-accumulated results to obtain the accumulated result.

5. The circuit according to claim 4, wherein the at least two adders comprise a first adder and a second adder, the first adder corresponds to a higher bit of a corresponding number of bits in the product, and the second adder corresponds to a lower bit of the corresponding number of bits in the product; and
the multiply-accumulator comprises a multiplication sub-circuit and a first addition sub-circuit, the multiplication sub-circuit is configured to multiply the sub-accumulated result corresponding to the first adder with a preset numerical value, and the first addition sub-circuit is configured to add a result output by the multiplication sub-circuit with the sub-accumulated result corresponding to the second adder to obtain the accumulated result.

6. The circuit according to claim 5, wherein the higher bit of the corresponding number of bits is the highest bit of the product, and the lower bit of the corresponding number of bits is another bit in the product different from the highest bit.

7. The circuit according to claim 1, wherein the multi-bit input transfer logic comprises a shifter and a second addition sub-circuit, and the shifter and the second addition sub-circuit are configured to perform cyclically:
inputting an accumulated result corresponding to a highest bit of the input feature data into the shifter, inputting a shifted accumulated result and an accumulated result corresponding to an adjacent lower bit into the second addition sub-circuit, inputting an added accumulated result into the shifter, and inputting another shifted accumulated result and another accumulated result corresponding to another adjacent lower bit into the second addition sub-circuit again, the multiply-accumulate result being obtained until an accumulated result corresponding to a lowest bit of the input feature data and yet another shifted accumulated result are input into the second addition sub-circuit.

8. The circuit according to claim 1, wherein the multi-bit input transfer logic comprises a target number of shifters and a third addition sub-circuit, the target number being the number of bits included in the input feature data minus one;
each of the target number of shifters is configured to shift an input accumulated result by a corresponding number of bits; and
the third addition sub-circuit is configured to add shifted accumulated results respectively output by the target number of shifters to obtain the multiply-accumulate result.

9. The circuit according to claim 2, further comprising a mode selection sub-circuit configured to select a current operation mode of the circuit according to an input mode selection signal, the operation mode comprising a normal read/write mode and a multi-bit multiply-accumulate mode;
in the normal read/write mode, the address decoder being further configured to select a target word line driver from the at least one word line driver according to an externally input write address signal or read address signal; and
the data read/write interface being further configured to write data to data storage cells included in respective computational storage cells corresponding to the selected target word line driver based on the write address signal, or read out data from the data storage cells included in respective computational storage cells corresponding to the selected target word line driver based on the read address signal.

10. The circuit according to claim 1, wherein the single-bit multiplier comprises a NOR gate configured to perform a NOR operation on a single bit included in inverted weight data and a single bit included in inverted input feature data to obtain single-bit product.

11. The circuit according to claim 2, wherein the single-bit multiplier comprises a NOR gate configured to perform a NOR operation on a single bit included in inverted weight data and a single bit included in inverted input feature data to obtain single-bit product.

12. The circuit according to claim 3, wherein the single-bit multiplier comprises a NOR gate configured to perform a NOR operation on a single bit included in inverted weight data and a single bit included in inverted input feature data to obtain single-bit product.

13. The circuit according to claim 4, wherein the single-bit multiplier comprises a NOR gate configured to perform a NOR operation on a single bit included in inverted weight data and a single bit included in inverted input feature data to obtain single-bit product.

14. The circuit according to claim 5, wherein the single-bit multiplier comprises a NOR gate configured to perform a NOR operation on a single bit included in inverted weight data and a single bit included in inverted input feature data to obtain single-bit product.

15. The circuit according to claim 6, wherein the single-bit multiplier comprises a NOR gate configured to perform a NOR operation on a single bit included in inverted weight data and a single bit included in inverted input feature data to obtain single-bit product.

16. The circuit according to claim 7, wherein the single-bit multiplier comprises a NOR gate configured to perform a NOR operation on a single bit included in inverted weight data and a single bit included in inverted input feature data to obtain single-bit product.

17. The circuit according to claim 8, wherein the single-bit multiplier comprises a NOR gate configured to perform a NOR operation on a single bit included in inverted weight data and a single bit included in inverted input feature data to obtain single-bit product.

18. The circuit according to claim 9, wherein the single-bit multiplier comprises a NOR gate configured to perform a NOR operation on a single bit included in inverted weight data and a single bit included in inverted input feature data to obtain single-bit product.
